(19) United States
(12) Patent Application Publication
(10) Pub. No.: US 2022/0351960 A1
(43) Pub. Date: Nov. 3, 2022

(54) Atomic Layer Deposition Of Metal Fluoride Films

(71) Applicant: Applied Materials, Inc., Santa Clara, CA (US)

(72) Inventors: Lisa J. Enman, Sunnyvale, CA (US); Mark Saly, Santa Clara, CA (US); Sanni Seppaelae, Santa Clara, CA (US); Gayatri Natu, Mumbai (IN)

(73) Assignee: Applied Materials, Inc., Santa Clara, CA (US)

(21) Appl. No.: 17/347,789

(22) Filed: Jun. 15, 2021

(30) Foreign Application Priority Data
May 3, 2021 (IN) 202141020155

(51) Int. Cl. H01L 21/02; C23C 16/455; C23C 16/30; C23C 16/56

(52) U.S. Cl. CPC H01L 21/0228; C23C 16/45553; C23C 16/30; C23C 16/56; H01L 21/02172; H01L 21/02318

(57) ABSTRACT

Methods and precursors for depositing metal fluoride films on a substrate surface are described. The method includes exposing the substrate surface to a metal precursor and a fluoride precursor. The fluoride precursor is volatile at a temperature in a range of from 20° C. to 200° C. The metal precursor reacts with the fluoride precursor to form a non-volatile metal fluoride film.

### CROSS-REFERENCE TO RELATED APPLICATIONS

This application claims priority to Indian Application No. 202141020155, filed May 3, 2021, the entire disclosure of which is hereby incorporated by reference herein.

### TECHNICAL FIELD

Embodiments of the disclosure relate to semiconductor devices and methods of manufacturing semiconductor devices. More particularly, embodiments of the disclosure are directed to methods for atomic layer deposition of metal fluoride films using fluorine precursors.

### BACKGROUND

Deposition of films on a substrate surface is an important process in a variety of industries. Metal fluoride films, in particular, are useful for such things including conformal protective coatings on chamber parts, semiconductor processing films, diffusion barrier coatings, optical coatings, and as dielectrics materials.

One method for deposition of films is atomic layer deposition (ALD). Most ALD processes are based on binary reaction sequences, where each of the two surface reactions occurs sequentially. Because the surface reactions are sequential, the two gas phase reactants are not in contact, and possible gas phase reactions that may form and deposit particles are limited.

Chamber parts are often exposed to harsh etch or deposition conditions (i.e., halide-based chemistries and plasmas). There are a limited number of metal fluoride atomic layer deposition methods which avoids the use of HF-pyridine, which is undesirable for safety reasons.

ALD of metal fluoride films often involves HF-pyridine or HF gas, which are toxic and require expensive delivery systems (gas detection, double walled delivery lines, and the like). HF-pyridine is undesirable due to safety concerns and costs associated with those safety concerns. Accordingly, there is a need for precursors and/or methods that avoid the use of HF-pyridine based precursors.

### SUMMARY

One or more embodiments of the disclosure are directed to a method of depositing a film. In one or more embodiments, a method of depositing a metal fluoride film comprises: exposing a substrate surface to a metal precursor, the metal precursor volatile at a temperature at a temperature in a range of from 20° C. to 200° C.; purging the substrate surface of the metal precursor; exposing the substrate surface to a fluoride precursor to form the metal fluoride film, the fluoride precursor volatile at a temperature in a range of from 20° C. to 200° C.; and purging the substrate surface of the fluoride precursor.

Additional embodiments of the disclosure are directed to a method of depositing a film. In one or more embodiments, a method of depositing a metal fluoride film comprises: exposing a substrate surface to a metal precursor, the metal precursor volatile at a temperature in a range of from 20° C. to 200° C.; purging the substrate surface of the metal precursor; exposing the substrate surface to an oxidizing agent at a temperature in a range of from 100° C. to 550° C.; purging the substrate surface of the oxidizing agent; exposing the substrate surface to a fluoride precursor at a temperature in a range of from 100° C. to 550° C. to form the metal fluoride film, the fluoride precursor volatile at a temperature in a range of from 20° C. to 200° C.; and purging the reaction chamber of the fluoride precursor, wherein the method is performed at a pressure in a range of from 0.01 Torr to 250 Torr.

Further embodiments of the disclosure are directed to a method of depositing a film. In one or more embodiments, a method of forming a metal fluoride film comprises: exposing a substrate surface to a metal precursor; purging the substrate surface of the metal precursor; exposing the substrate surface to an oxidizing agent to form a metal oxide film; purging the substrate surface of the oxidizing agent; in situ annealing the metal oxide film in a fluoride precursor, the fluoride precursor volatile at a temperature in a range of from 20° C. to 200° C. to form a metal fluoride film.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2 illustrates a process flow diagram of a method in accordance with one or more embodiments of the disclosure;

FIG. 3 illustrates a process flow diagram of a method in accordance with one or more embodiments of the disclosure;

FIG. 4A illustrates a cross-sectional view of a substrate according to one or more embodiments; and

FIG. 4B illustrates a cross-sectional view of a substrate according to one or more embodiments.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

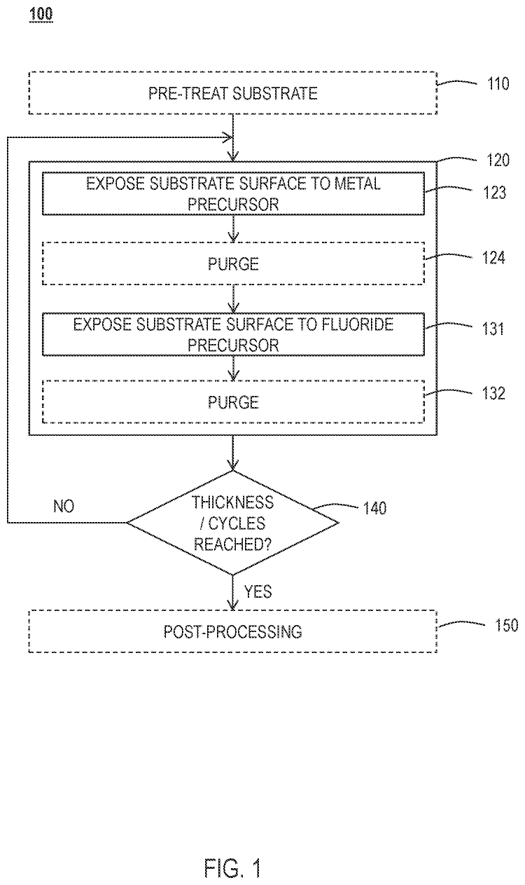

Embodiments of the disclosure provide methods for depositing metal fluoride films on a substrate. FIG. 1 illustrates a method 100 for depositing a metal fluoride film. In some embodiments, the method 100 comprises exposing a substrate surface to a metal precursor (operation 123), exposing the substrate surface to a fluoride precursor (operation 131), and repeating the operation 123 and operation 131 until the metal fluoride film has a pre-determined thickness. In some embodiments, the method 100 further comprises one or more of pre-treating the substrate surface (operation 110), purging the substrate of the metal precursor (operation 124), purging the substrate of the fluoride precursor (operation 132) and performing post-processing (operation 150).

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

The term “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal oxides, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The substrate (or substrate surface) may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate surface such that the metal oxide may be at least partially formed thereon. For example, in some embodiments, a layer comprising a metal, a nitride, an oxide, or the like, or combinations thereof may be disposed on the substrate and may have the metal containing layer formed upon such layer or layers.

In some embodiments, the substrate may comprise one or more of a semiconductor substrate, a processing chamber component, a workpiece, a pedestal, and a heater. As used herein, the term “workpiece” refers to any component, part of a component or device, or any object that can be integrated, into a larger and/or more complex component or device.

As used herein, the term “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the metal oxide film, for example, by polishing, etching, reduction, oxidation, halogenation, hydroxylation, annealing, baking, or the like.

As used herein, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of one or more reactive compounds by any suitable technique including, but not limited to, moving the substrate through a gas curtain to a portion or sector of the processing chamber that contains none or substantially none of the reactive compounds.

As used in this specification and the appended claims, the terms “reactive compound”, “reactive gas”, “reactive species”, “precursor”, “process gas” and the like are used interchangeably to refer to any gaseous species that can react with the substrate surface or material on the substrate surface in a surface reaction (e.g., chemisorption, oxidation, reduction). In one or more embodiments, the reactive gas comprises the metal precursor, the fluoride precursor, an oxidative agent or a combination thereof.

In some embodiments, the method 100 includes an optional pre-treatment operation 110. The pre-treatment can be any suitable pre-treatment known to the skilled artisan. Suitable pre-treatments include, but are not limited to, pre-heating, cleaning, soaking, native oxide removal, or deposition of an adhesion layer. In one or more embodiments, an adhesion layer is deposited at operation 110.

At deposition process cycle 120, a process is performed to deposit the metal fluoride film on the substrate surface in the processing chamber. The deposition process cycle 120 can include one or more operations to form the metal fluoride film on the substrate. In some embodiments, the deposition process cycle 120 comprises exposing the substrate surface to the metal precursor (operation 123) and exposing the substrate surface to the fluoride precursor (operation 131). In some embodiments, the deposition process cycle 120 further comprises one or more of purging the substrate surface of the metal precursor (operation 124) and purging the substrate surface of the fluoride precursor (operation 132).

In one or more embodiments, one or more of the metal precursor and the fluoride precursor are volatile and thermally stable, and, thus, suitable for vapor deposition. In some embodiments, the metal fluoride film is deposited by a vapor deposition technique. In some embodiments, the vapor depositing technique comprises an atomic layer deposition (ALD) and/or chemical vapor deposition (CVD).

According to one or more embodiments, the deposition process cycle 120 uses an atomic layer deposition (ALD) process. In such embodiments, the substrate surface is exposed to the reactive gases sequentially or substantially sequentially. As used herein throughout the specification, “substantially sequentially” means that a majority of the duration of a precursor exposure does not overlap with the exposure to a co-reagent, although there may be some overlap.

In some embodiments, the deposition process cycle 120 comprises an atomic layer deposition (ALD) process in which the substrate or substrate surface is exposed sequentially to the reactive gases in a manner that prevents or minimizes gas phase reactions of the reactive gases. In the embodiment illustrated in FIG. 1, at deposition process cycle 120, the substrate surface is exposed to the metal precursor (operation 123) and the fluoride precursor (operation 131) sequentially.

“Atomic layer deposition” or “cyclical deposition” as used herein refers to the sequential exposure of two or more reactive compounds to deposit a layer of material on a substrate surface. The substrate, or portion of the substrate surface is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness. In one or more embodiments, the time-domain ALD process can be performed with more than two reactive compounds in a predetermined sequence.

In an aspect of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. In one or more embodiments, the spatial ALD process can be performed with more than two reactive compounds in a predetermined sequence.

In some unillustrated embodiments, the metal fluoride film is deposited by a chemical vapor deposition (CVD) process. In some embodiments, the chemical vapor deposition (CVD) process comprises mixing the reactive compounds in the processing chamber to allow gas phase reactions of the reactive compounds and depositing the metal fluoride film. In some embodiments, the substrate (or substrate surface) is exposed to two or more reactive compounds simultaneously in a CVD reaction. In the CVD reaction, the substrate (or substrate surface) can be exposed to a gaseous mixture of two or more reactive compounds to deposit the metal fluoride film having a predetermined thickness. In the CVD reaction, the metal fluoride film can be deposited in one exposure to the mixed reactive compounds, or can be multiple exposures to the mixed reactive compounds with purges between.

In operation 123, the substrate surface is exposed to the metal precursor to deposit a metal precursor film on the substrate surface. The metal precursor can be any suitable metal-containing compound that can react with (i.e., adsorb or chemisorb onto) the substrate surface to leave a metal-containing species on the substrate surface. In some embodiments, the metal precursor comprises a metal selected from aluminum (Al), magnesium (Mg), calcium (Ca), strontium (Sr), barium (Ba), scandium (Sc), yttrium (Y), zirconium (Zr), hafnium (Hf), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or combinations thereof. In some embodiments, the metal precursor comprises a metal selected from one or more of scandium (Sc), yttrium (Y), zirconium (Zr), hafnium (Hf), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), and ytterbium (Yb). In some embodiments, the metal precursor includes an organometallic compound.

In some embodiments, the organometallic compound comprises one or more of metal alkyl compounds or derivatives thereof, metal allyl compounds or derivatives thereof, metal cyclopentadienyl compounds or derivatives thereof, metal amide compounds or derivatives thereof, metal amidine compounds or derivatives thereof, metal alkoxide compounds or derivatives thereof, metal aminoalkoxide compounds or derivatives thereof, and metal 1,4-diaza-1,3-diene compounds or derivatives thereof. In some embodiments, the organometallic compound comprises a compound of general formula (I)

MR_{z} (I)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; R is N_{w}CₓH_{y}, wherein w is 0 or 1, x is in a range of from 1 to 20, and y is in a range of from 3 to 60; and z is a charge on the metal M. In some embodiments, z is in a range of from 1 to 4.

In one or more embodiments, the organometallic compound comprises a metal alkyl compound. In some embodiments, the metal alkyl compound has a general formula (II)

M(Rₐ)_{z} (II)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; Rₐ is CₓH_{y}, wherein x is in a range of from 1 to 20, and y is in a range of from 3 to 60; and z is a charge on the metal M. In some embodiments, Rₐ is a linear hydrocarbon, a branched hydrocarbon, or derivatives thereof. In some embodiments, z is in a range of from 1 to 4.

In one or more embodiments, the organometallic compound comprises a metal allyl compound. In some embodiments, the metal allyl compound has a general formula (III)

M(R_{b})_{z} (III)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; R_{b} is CₓH_{y}, wherein x is in a range of from 2 to 20, and y is in a range of from 2 to 60; and z is a charge on the metal M. In some embodiments, R_{b} is a cyclic hydrocarbon or derivative thereof. In some embodiments, z is in a range of from 1 to 4.

In one or more embodiments, the organometallic compound comprises a metal cyclopentadienyl compound. In some embodiments, the metal cyclopentadienyl compound has a general formula (IV)

M((C₅Hₓ)(R_{c})_{y})_{z} (IV)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; R_{c} is independently alkyl; x is a number in a range of from 1 to 5; y is a number in a range of from 1 to 5; and z is a charge on metal center. In some embodiments, z is in a range of from 1 to 4.

As used herein, “alkyl,” or “alk” includes both straight and branched chain hydrocarbons, containing 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. In one or more embodiments, R_{c} is a C₁₋₆ alkyl.

In one or more embodiments, the organometallic compound comprises a metal amide compound. In some embodiments, the metal amide compound has a general formula (V)

M(N(R_{d})₂)_{z} (V)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; R_{d} is independently alkyl; and z is a charge on the metal M. In some embodiments, z is in a range of from 1 to 4.

In one or more embodiments, the organometallic compound comprises a metal amidine compound. In some embodiments, the metal amidine compound has a general formula (VI)

M(R_{f}NCR_{f}NR_{f})_{z} (VI)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combination thereof; R_{f} is independently N_{w}CₓH_{y}, where w is 0 or 1, x is in a range of from 0 to 5, and y is in a range of from 1 to 15; and z is a charge on the metal M. In some embodiments, z is in a range of from 1 to 4. In some embodiments, the metal amidine compound comprises one or more of formamidinate, amidinate, guanidinate or derivative thereof.

In one or more embodiments, the organometallic compound comprises a metal alkoxide compound. In some embodiments, the metal alkoxide compound has a general formula (VII)

M(OR_{g})_{z} (VII)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; R_{g} is independently alkyl; and z is a charge on the metal M. In some embodiments, z is in a range of from 1 to 4.

In one or more embodiments, the organometallic compound comprises a metal aminoalkoxide compound. In some embodiments, the metal aminoalkoxide compound has a general formula (VIII)

M((Rₕ)₂NC(Rₕ)C(Rₕ)ORₕ)_{z} (VIII)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; Rₕ is independently alkyl; and z is a charge on the metal M. In some embodiments, z is in a range of from 1 to 4.

In one or more embodiments, the organometallic compound comprises a metal 1,4-Diaza-1,3-diene compound. In some embodiments, the metal 1,4-Diaza-1,3-diene compound has a general formula (IX)

M(RᵢNC(Rᵢ)C(Rᵢ)NRᵢ)_{z} (IX)

wherein M is a metal selected from Al, Mg, Ca, Sr, Ba, Sc, Y, Zr, Hf, La, Ce, Pr, Nd, Sm, Eu, Gd, Tb, Dy, Ho, Er, Tm, Yb, or combinations thereof; Rᵢ is independently alkyl; and z is a charge on the metal M. In some embodiments, z is in a range of from 1 to 4.

In one or more embodiments, the metal precursor may comprise one or more of a compound of general formula (I), a compound of general formula (II), a compound of general formula (III), a compound of general formula (IV), a compound of general formula (V), a compound of general formula (VI), a compound of general formula (VII), a compound of general formula (VIII), and a compound of general formula (IX).

In one or more embodiments, the metal precursor is volatile at a temperature in a range of from 20° C. to 200° C., from 25° C. to 200° C., from 50° C. to 200° C., from 75° C. to 200° C., or from 100° C. to 200° C. In some embodiments, the metal precursor is volatile at a temperature less than 200° C., including less than 175° C., less than 150° C., less than 125° C., less than 100° C., less than 75° C., less than 50° C., and less than 25° C. In one or more embodiments, the metal precursor is sufficiently volatile in at least part of the temperature range of from 20° C. to 200° C.

In one or more embodiments, the metal precursor is stable at a temperature in a range of from 20° C. to 550° C., from 20° C. to 450° C., from 20° C. to 350° C., from 20° C. to 250° C., from 50° C. to 550° C., from 50° C. to 450° C., from 50° C. to 350° C., from 50° C. to 250° C., from 100° C. to 550° C., from 100° C. to 450° C., from 100° C. to 350° C., from 100° C. to 250° C., from 200° C. to 550° C., from 200° C. to 450° C., from 200° C. to 350° C., from 300° C. to 550° C., from 300° C. to 450° C. or from 400° C. to 550° C. In some embodiments, the metal precursor is stable at a temperature in a range of from 20° C. to <550° C., from 20° C. to <450° C., from 20° C. to <350° C., from 20° C. to <250° C., from 50° C. to <550° C., from 50° C. to <450° C., from 50° C. to <350° C., from 50° C. to <250° C., from 100° C. to <550° C., from 100° C. to <450° C., from 100° C. to <350° C., from 100° C. to <250° C., from 200° C. to <550° C., from 200° C. to <450° C., from 200° C. to <350° C., from 300° C. to <550° C., from 300° C. to <450° C. or from 400° C. to <550° C. In one or more embodiments, the metal precursor does not decompose in at least part of a temperature range of from 100° C. to 550° C.

In one or more embodiments, the metal precursor reacts with a fluoride precursor to form a metal fluoride film. In some embodiments, the metal fluoride film is non-volatile. In some embodiments, the metal precursor reacts with the fluoride precursor to form a non-volatile metal fluoride film and volatile byproducts of the metal precursor ligand. In some embodiments, metal precursor does not react with itself.

In one or more embodiments, the metal precursor is flowed in a carrier gas. In some embodiments, the carrier gas in an inert gas. In some embodiments, the inert gas comprises one or more of N₂, Ar, and He.

In one or more embodiments, the metal precursor is mixed with a reactant. In some embodiments, the reactant comprises an oxidizing agent. In one or more embodiments, the oxidizing agent can comprise any suitable oxidizing agent known to one of skill in the art. In some embodiments, the oxidizing agent comprises H₂O, H₂O₂, O₂, ozone, O₂ plasma, or combinations thereof. In some embodiments, the metal precursor is mixed with the reactant in a carrier gas.

At operation 124, the substrate surface is optionally purged to remove unreacted metal precursor, reaction products and/or by-products. In one or more embodiments, purging the substrate surface comprises applying a vacuum. In some embodiments, purging the substrate surface comprises flowing a purge gas over the substrate. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar).

At operation 131, the substrate surface is exposed to a fluoride precursor to form a metal fluoride film on the substrate. The fluoride precursor can react with the metal precursor film or species on the substrate surface to form the metal fluoride film. In some embodiments, the metal fluoride film is non-volatile.

In one or more embodiments, the fluoride precursor reacts with the metal precursor film or species at a temperature in a range of from 100° C. to 550° C., from 100° C. to 450° C., from 100° C. to 350° C., from 100° C. to 250° C., from 150° C. to 550° C., from 150° C. to 450° C., from 150° C. to 350° C., from 150° C. to 250° C., from 200° C. to 550° C., from 200° C. to 450° C., from 200° C. to 350° C., from 200° C. to 250° C., from 250° C. to 550° C., from 250° C. to 450° C., from 250° C. to 350° C., from 300° C. to 550° C., from 300° C. to 450° C., or from 400° C. to 550° C.

In one or more embodiments, the fluoride precursor reacts with the metal precursor film or species at a temperature in a range of from 100° C. to 550° C., from 100° C. to 450° C., from 100° C. to 350° C., from 100° C. to 250° C., from 150° C. to 550° C., from 150° C. to 450° C., from 150° C. to 350° C., from 150° C. to 250° C., from 200° C. to 550° C., from 200° C. to 450° C., from 200° C. to 350° C., from 200° C. to 250° C., from 250° C. to 550° C., from 250° C. to 450° C., from 250° C. to 350° C., from 300° C. to 550° C., from 300° C. to 450° C., or from 400° C. to 550° C.

In one or more embodiments, the fluoride precursor reacts with the metal precursor film or species at a pressure in a range of from 0.01 Torr to 760 Torr, from 0.01 Torr to 500 Torr, from 0.01 Torr to 250 Torr, from 0.01 Torr to 200 Torr, from 0.01 Torr to 150 Torr, from 0.01 Torr to 100 Torr, from 0.01 Torr to 50 Torr, from 0.5 Torr to 760 Torr, from 0.5 Torr to 500 Torr, from 0.5 Torr to 250 Torr, from 0.5 Torr to 200 Torr, from 0.5 Torr to 150 Torr, from 0.5 Torr to 100 Torr, from 0.5 Torr to 50 Torr, from 1 Torr to 760 Torr, from 1 Torr to 500 Torr, from 1 Torr to 250 Torr, from 1 Torr to 200 Torr, from 1 Torr to 150 Torr, from 1 Torr to 100 Torr, from 1 Torr to 50 Torr, from 5 Torr to 760 Torr, from 5 Torr to 500 Torr, from 5 Torr to 250 Torr, from 5 Torr to 200 Torr, from 5 Torr to 150 Torr, from 5 Torr to 100 Torr, from 5 Torr to 50 Torr, from 10 Torr to 760 Torr, from 10 Torr to 500 Torr, from 10 Torr to 250 Torr, from 10 Torr to 200 Torr, from 10 Torr to 150 Torr, from 10 Torr to 100 Torr, from 10 Torr to 50 Torr, from 25 Torr to 760 Torr, from 25 Torr to 500 Torr, from 25 Torr to 250 Torr, from 25 Torr to 200 Torr, from 25 Torr to 150 Torr, from 25 Torr to 100 Torr, from 25 Torr to 50 Torr, from 50 Torr to 760 Torr, from 50 Torr to 500 Torr, from 50 Torr to 250 Torr, from 50 Torr to 200 Torr, from 50 Torr to 150 Torr, from 50 Torr to 100 Torr, from 100 Torr to 760 Torr, from 100 Torr to 500 Torr, from 100 Torr to 250 Torr, from 100 Torr to 200 Torr, from 100 Torr to 150 Torr, from 150 Torr to 760 Torr, from 150 Torr to 500 Torr, from 150 Torr to 250 Torr, from 150 Torr to 200 Torr, from 200 Torr to 760 Torr, from 200 Torr to 500 Torr, or from 200 Torr to 250 Torr.

In one or more embodiments, the fluoride precursor is selected from a volatile metal fluoride, F₂, HF, NH₄F, BF₃, SF₄, SF₆ plasma, NF₃, NF₃ plasma, SOF₂, COF₂, POF₃, CIF₃, R—SO₂F (e.g. perfluorobutanesulfonyl fluoride), N,N-diethylaminosulfur trifluoride (DAST), bis(2-methoxyethyl)-aminosulfur trifluoride (Deoxo-Fluor®), 4-tert-butyl-2,6-dimethylphenylsulfur trifluoride (Fluolead®), or combinations thereof. In some embodiments, the volatile metal fluoride is selected from TiF₄, NbF₅, TaF₅, VF₅, WF₆, WF₅, MoF₆, MoF₅, or combinations thereof. In one or more embodiments, the fluoride precursor is selected from a volatile metal fluoride, F₂, HF, NH₄F, BF₃, SF₄, SF₆ plasma, NF₃ plasma, SOF₂, COF₂, POF₃, CIF₃, or combinations thereof. In some embodiments, the fluoride precursor comprises NF₃, NF₃ plasma, F₂, CIF₃, or combinations thereof. In some embodiments, the fluoride precursor comprises a volatile metal fluoride, SOF₂, COF₂, POF₃, CIF₃, SF₄, R—SO₂F (eg. perfluorobutanesulfonyl fluoride), N,N-diethylaminosulfur trifluoride (DAST), bis(2-methoxyethyl)-aminosulfur trifluoride (Deoxo-Fluor®), 4-tert-butyl-2,6-dimethylphenylsulfur trifluoride (Fluolead®), or combinations thereof.

In one or more embodiments, the fluoride precursor is flowed in a carrier gas. In one or more embodiments, the carrier gas in an inert gas. In some embodiments, the inert gas comprises one or more of N₂, Ar, and He. In one or more embodiments, the fluoride precursor is mixed with a reactant. In some embodiments, the reactant comprises an oxidizing agent. In one or more embodiments, the oxidizing agent can comprise any suitable oxidizing agent known to one of skill in the art. In one or more embodiments, the oxidizing agent comprises H₂O, H₂O₂, O₂, ozone, O₂ plasma, or combinations thereof. In some embodiments, the fluoride precursor is mixed with the reactant and the carrier gas.

At operation 132, the substrate surface is optionally purged after exposure to the fluoride precursor. Purging the substrate surface in operation 132 can be the same process or different process than the purge in operation 124. Purging the substrate surface, the processing chamber, a portion of the processing chamber, an area adjacent the substrate surface, etc., removes unreacted fluoride precursor, reaction products and by-products from the area adjacent the substrate surface.

At decision 140, the thickness of the deposited film, or number of deposition process cycles 120 is considered. If the deposited film has reached a predetermined thickness or a predetermined number of process cycles 120 have been performed, the method 100 moves to an optional post-processing operation 150. In some embodiments, the deposition process cycle 120 comprises sequential exposure of the substrate surface to the metal precursor, purge gas, fluoride precursor, and purge gas. If the thickness of the deposited film or the number of process cycles has not reached the predetermined threshold, the method 100 returns to deposition process cycle 120 to expose the substrate surface to the metal precursor again in operation 123, and continuing.

In one or more embodiments, the predetermined thickness is greater than 1 nm, greater than 10 nm, greater than 25 nm, greater than 100 nm, greater than 500 nm, or greater than 1000 nm. In one or more embodiments, the predetermined thickness is in a range of from 1 nm to 5000 nm, from 1 nm to 4000 nm, from 1 nm to 3000 nm, from 1 nm to 2000 nm, from 1 nm to 1000 nm, from 1 nm to 500 nm, from 1 nm to 400 nm, from 1 nm to 300 nm, from 1 nm to 200 nm, from 1 nm to 100 nm, from 1 nm to 50 nm, from 5 nm to 5000 nm, from 5 nm to 4000 nm, from 5 nm to 3000 nm, from 5 nm to 2000 nm, from 5 nm to 1000 nm, from 5 nm to 500 nm, from 5 nm to 400 nm, from 5 nm to 300 nm, from 5 nm to 200 nm, from 5 nm to 100 nm, from 5 nm to 50 nm, from 10 nm to 5000 nm, from 10 nm to 4000 nm, from 10 nm to 3000 nm, from 10 nm to 2000 nm, from 10 nm to 1000 nm, from 10 nm to 500 nm, from 10 nm to 400 nm, from 10 nm to 300 nm, from 10 nm to 200 nm, from 10 nm to 100 nm, from 10 nm to 50 nm, from 25 nm to 5000 nm, from 25 nm to 4000 nm, from 25 nm to 3000 nm, from 25 nm to 2000 nm, from 25 nm to 1000 nm, from 25 nm to 500 nm, from 25 nm to 400 nm, from 25 nm to 300 nm, from 25 nm to 200 nm, from 25 nm to 100 nm, from 25 nm to 50 nm, from 50 nm to 5000 nm, from 50 nm to 4000 nm, from 50 nm to 3000 nm, from 50 nm to 2000 nm, from 50 nm to 1000 nm, from 50 nm to 500 nm, from 50 nm to 400 nm, from 50 nm to 300 nm, from 50 nm to 200 nm, from 50 nm to 100 nm, from 100 nm to 5000 nm, from 100 nm to 4000 nm, from 100 nm to 3000 nm, from 100 nm to 2000 nm, from 100 nm to 1000 nm, from 100 nm to 500 nm, from 100 nm to 400 nm, from 100 nm to 300 nm or from 100 nm to 200 nm.

In one or more embodiments, the predetermined number of deposition process cycles is in a range of from 10 to 100000, from 10 to 50000, from 10 to 20000, from 10 to 10000, from 10 to 5000, from 10 to 2000, from 10 to 1000, from 10 to 500 or from 10 to 100.

The optional post-processing operation 150 can be, for example, a process to modify film properties (e.g., annealing) or a further film deposition process (e.g., additional ALD or CVD processes) to grow additional films. In some embodiments, the optional post-processing operation 150 can be a process that modifies a property of the deposited film. In some embodiments, the optional post-processing operation 150 comprises annealing the as-deposited film. In some embodiments, annealing is performed at temperatures in the range of from 100° C. to 550° C., from 100° C. to 450° C., from 100° C. to 350° C., from 100° C. to 250° C., from 200° C. to 550° C., from 200° C. to 450° C., from 200° C. to 350° C., from 300° C. to 550° C., from 300° C. to 450° C. or from 400° C. to 550° C. In some embodiments, the annealing is performed at a temperature in a range of from 100° C. to <550° C., from 100° C. to <450° C., from 100° C. to <350° C., from 100° C. to <250° C., from 200° C. to <550° C., from 200° C. to <450° C., from 200° C. to <350° C., from 300° C. to <550° C., from 300° C. to <450° C. or from 400° C. to <550° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of from 1 hour to 24 hour, from 1 hour to 20 hour, from 1 hour to 15 hour, from 1 hour to 10 hour, from 1 hour to 5 hour, from 5 hour to 24 hour, from 5 hour to 20 hour, from 5 hour to 15 hour, from 5 hour to 10 hour, from 10 hour to 24 hour, from 10 hour to 20 hour, from 10 hour to 15 hour, from 15 hour to 24 hour, from 15 hour to 20 hour or from 20 hour to 24 hour. In some embodiments, annealing the as-deposited film increases the density, decreases the resistivity and/or increases the purity of the film.

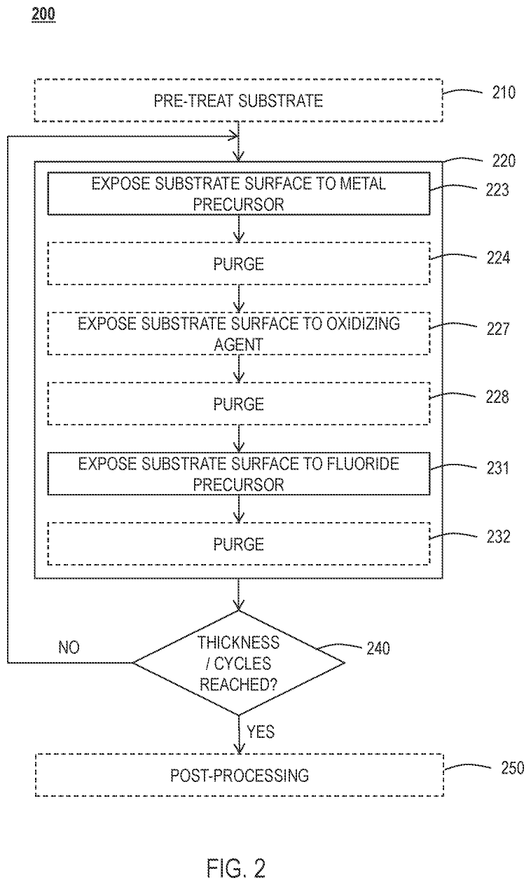

FIG. 2 illustrates a method 200 for depositing a metal fluoride film. In one or more embodiments, the method 200 comprises exposing the substrate surface to the metal precursor (operation 223), exposing the substrate surface to the oxidizing agent (operation 227), exposing the substrate surface to a fluoride precursor (operation 231) to deposit the metal fluoride film, and repeating the method until the metal fluoride film has reached the predetermined thickness or the predetermined number of deposition process cycle 220 (decision 240). In some embodiments, the method 200 comprises one or more of pre-treating the substrate surface (operation 210), purging the substrate surface of the metal precursor (operation 224), purging the substrate surface of the oxidizing agent (operation 228), purging the substrate surface of the fluoride precursor (operation 232) and performing post-processing (operation 250). Suitable metal precursors and fluoride precursors for use in the method 200 are the same metal precursors and fluoride precursors as described herein for use in method 100.

In atomic layer etching (ALE) processes, a metal oxide and a fluoride source are reacted to form a metal fluoride in situ. The metal fluoride is not isolated and is then directly exposed to a halide etchant to remove the metal fluoride layer. In an ALE method, in contrast to the method of one of more embodiments, an isolated metal fluoride film is not formed. An ALE method is a top-down approach to remove a metal oxide film. It removes an oxide film with sequential chemical exposures. An ALE method never forms a bulk pure fluoride film, but, rather, an oxide film with some metal fluoride at the surface. The method of one or more embodiments, herein, on the other hand, deposits a metal fluoride with sequential chemical exposures. The method of one or more embodiments is a bottom-up approach to form a metal fluoride film, ideally without any oxygen remaining. In one or more embodiments herein, a metal oxide is reacted with a fluoride precursor to deposit and isolate a metal fluoride layer on the substrate surface.

At operation 227, the substrate surface is exposed to the oxidizing agent to form a metal oxide film. The oxidizing agent reacts with the metal containing species on the substrate surface to form the metal oxide film. In one or more embodiments, the oxidizing agent can comprise any suitable oxidizing agent known to one of skill in the art. In some embodiments, the oxidizing agent comprises H₂O, H₂O₂, O₂, ozone, O₂ plasma, or combinations thereof. In one or more embodiments, the oxidizing agent is flowed in a carrier gas. In one or more embodiments, the carrier gas in an inert gas. In some embodiments, the inert gas comprises one or more of N₂, Ar, and He.

At operation 228, the substrate surface is optionally purged after exposure to the oxide precursor. Purging the substrate surface in operation 228 can be the same process or different process than the purge in operation 224. Purging the substrate surface, the processing chamber, a portion of the processing chamber, an area adjacent the substrate surface, etc., removes unreacted oxidizing agent, reaction products and by-products from the area adjacent the substrate surface.

The method 200 can be performed at any suitable temperature depending on, for example, the metal precursor, the oxidizing agent, fluoride precursor, or thermal budget of the device. In one or more embodiments, the use of high temperature processing may be undesirable for temperature-sensitive substrates, such as logic devices. In some embodiments, exposure to the metal precursor (operation 223), exposure to the oxidizing agent (operation 227) and the fluoride precursor (operation 231) occur at the same temperature. In some embodiments, the substrate is maintained at a temperature in a range of from 100° C. to 550° C., from 100° C. to 450° C., from 100° C. to 350° C., from 100° C. to 250° C., from 150° C. to 550° C., from 150° C. to 450° C., from 150° C. to 350° C., from 150° C. to 250° C., from 200° C. to 550° C., from 200° C. to 450° C., from 200° C. to 350° C., from 200° C. to 250° C., from 250° C. to 550° C., from 250° C. to 450° C., from 250° C. to 350° C., from 300° C. to 550° C., from 300° C. to 450° C., or from 400° C. to 550° C.

In some embodiments, one or more of the exposure to the metal precursor (operation 223), the oxidizing agent (operation 227), and the fluoride precursor (operation 231) occur independently at a different temperature. In some embodiments, the substrate surface is exposed to the oxidizing agent (operation 227) at a temperature in a range of from 100° C. to 550° C., from 100° C. to 450° C., from 100° C. to 350° C., from 100° C. to 250° C., from 200° C. to 550° C., from 200° C. to 450° C., from 200° C. to 350° C., from 300° C. to 550° C., from 300° C. to 450° C. or from 400° C. to 550° C. In some embodiments, the substrate surface is exposed to the oxidizing agent (operation 227) at a first temperature in a range of from 100° C. to <550° C., from 100° C. to <450° C., from 100° C. to <350° C., from 100° C. to <250° C., from 200° C. to <550° C., from 200° C. to <450° C., from 200° C. to <350° C., from 300° C. to <550° C., from 300° C. to <450° C. or from 400° C. to <550° C.

The method 200 can be performed at any suitable pressure depending on, for example, properties of the metal precursor, the oxidizing agent, fluoride precursor or the device. In one or more embodiments, exposure to the metal precursor (operation 223), the oxidizing agent (operation 227) and the fluoride precursor (operation 231) occur at the same pressure. In some embodiments, the substrate is maintained at a pressure in a range of from 0.01 Torr to 760 Torr, from 0.01 Torr to 500 Torr, from 0.01 Torr to 250 Torr, from 0.01 Torr to 200 Torr, from 0.01 Torr to 150 Torr, from 0.01 Torr to 100 Torr, from 0.01 Torr to 50 Torr, from 0.5 Torr to 760 Torr, from 0.5 Torr to 500 Torr, from 0.5 Torr to 250 Torr, from 0.5 Torr to 200 Torr, from 0.5 Torr to 150 Torr, from 0.5 Torr to 100 Torr, from 0.5 Torr to 50 Torr, from 1 Torr to 760 Torr, from 1 Torr to 500 Torr, from 1 Torr to 250 Torr, from 1 Torr to 200 Torr, from 1 Torr to 150 Torr, from 1 Torr to 100 Torr, from 1 Torr to 50 Torr, from 5 Torr to 760 Torr, from 5 Torr to 500 Torr, from 5 Torr to 250 Torr, from 5 Torr to 200 Torr, from 5 Torr to 150 Torr, from 5 Torr to 100 Torr, from 5 Torr to 50 Torr, from 10 Torr to 760 Torr, from 10 Torr to 500 Torr, from 10 Torr to 250 Torr, from 10 Torr to 200 Torr, from 10 Torr to 150 Torr, from 10 Torr to 100 Torr, from 10 Torr to 50 Torr, from 25 Torr to 250 Torr, from 25 Torr to 760 Torr, from 25 Torr to 500 Torr, from 25 Torr to 200 Torr, from 25 Torr to 150 Torr, from 25 Torr to 100 Torr, from 25 Torr to 50 Torr, from 50 Torr to 760 Torr, from 50 Torr to 500 Torr, from 50 Torr to 250 Torr, from 50 Torr to 200 Torr, from 50 Torr to 150 Torr, from 50 Torr to 100 Torr, from 100 Torr to 760 Torr, from 100 Torr to 500 Torr, from 100 Torr to 250 Torr, from 100 Torr to 200 Torr, from 100 Torr to 150 Torr, from 150 Torr to 760 Torr, from 150 Torr to 500 Torr, from 150 Torr to 250 Torr, from 150 Torr to 200 Torr, from 200 Torr to 760 Torr, from 200 Torr to 500 Torr or from 200 Torr to 250 Torr.

In some embodiments, one or more of the exposure to the metal precursor (operation 223), the oxidizing agent (operation 227) and the fluoride precursor (operation 231) occur independently at a different pressure. In some embodiments, the substrate surface is exposed to the oxidizing agent (operation 227) at a first pressure in a range of from 0.01 Torr to 760 Torr, from 0.01 Torr to 500 Torr, from 0.01 Torr to 250 Torr, from 0.01 Torr to 200 Torr, from 0.01 Torr to 150 Torr, from 0.01 Torr to 100 Torr, from 0.01 Torr to 50 Torr, from 0.5 Torr to 760 Torr, from 0.5 Torr to 500 Torr, from 0.5 Torr to 250 Torr, from 0.5 Torr to 200 Torr, from 0.5 Torr to 150 Torr, from 0.5 Torr to 100 Torr, from 0.5 Torr to 50 Torr, from 1 Torr to 760 Torr, from 1 Torr to 500 Torr, from 1 Torr to 250 Torr, from 1 Torr to 200 Torr, from 1 Torr to 150 Torr, from 1 Torr to 100 Torr, from 1 Torr to 50 Torr, from 5 Torr to 760 Torr, from 5 Torr to 500 Torr, from 5 Torr to 250 Torr, from 5 Torr to 200 Torr, from 5 Torr to 150 Torr, from 5 Torr to 100 Torr, from 5 Torr to 50 Torr, from 10 Torr to 760 Torr, from 10 Torr to 500 Torr, from 10 Torr to 250 Torr, from 10 Torr to 200 Torr, from 10 Torr to 150 Torr, from 10 Torr to 100 Torr, from 10 Torr to 50 Torr, from 25 Torr to 760 Torr, from 25 Torr to 500 Torr, from 25 Torr to 250 Torr, from 25 Torr to 200 Torr, from 25 Torr to 150 Torr, from 25 Torr to 100 Torr, from 25 Torr to 50 Torr, from 50 Torr to 760 Torr, from 50 Torr to 500 Torr, from 50 Torr to 250 Torr, from 50 Torr to 200 Torr, from 50 Torr to 150 Torr, from 50 Torr to 100 Torr, from 100 Torr to 760 Torr, from 100 Torr to 500 Torr, from 100 Torr to 250 Torr, from 100 Torr to 200 Torr, from 100 Torr to 150 Torr, from 150 Torr to 760 Torr, from 150 Torr to 500 Torr, from 150 Torr to 250 Torr, from 150 Torr to 200 Torr, from 200 Torr to 760 Torr, from 200 Torr to 500 Torr or from 200 Torr to 250 Torr.

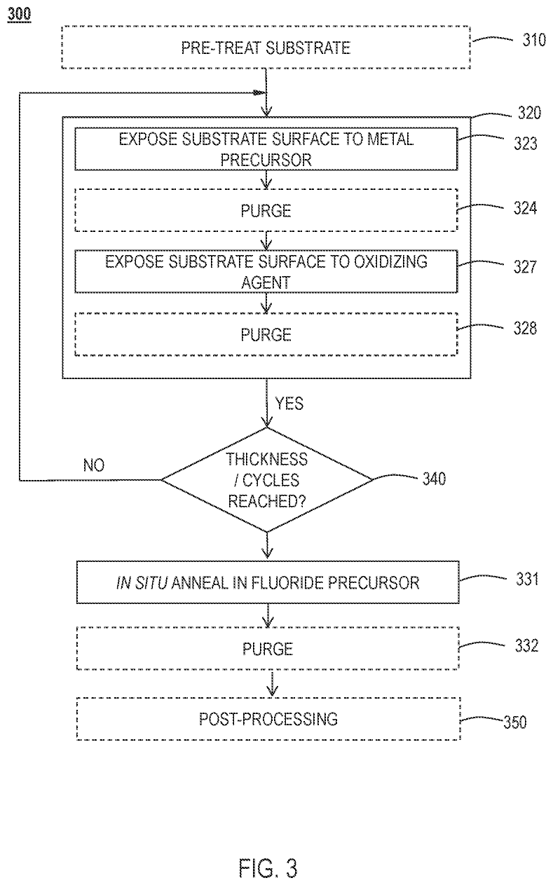

FIG. 3 illustrates a method 300 for depositing a metal fluoride film. In one or more embodiments, the method 300 comprises exposing the substrate surface to the metal precursor (operation 323) and an oxidizing agent (operation 327) to form a metal oxide film, repeating the method until the metal oxide film has reached a predetermined thickness (decision point 340) or a predetermined numbers of deposition process cycles 320. The metal oxide film is then in situ annealed in a fluoride precursor (operation 331) to form the metal fluoride film. In some embodiments, the method 300 comprises one or more of pre-treating the substrate surface (operation 310), purging the substrate surface of the metal precursor (operation 324), purging the substrate surface of the oxidizing agent (operation 328), purging the substrate surface of the fluoride precursor (operation 332) and performing post-processing (operation 350). Suitable metal precursors and fluoride precursors for use in the method 300 are the same metal precursors and fluoride precursors as described herein for use in method 100.

In one or more embodiments, the annealing operation 331 is performed in situ in the fluorine precursor at a temperature in the range of from 100° C. to 700° C.

In one or more embodiments, the annealing operation 345 is performed at a pressure in a range of from 0.01 Torr to 760 Torr, from 0.01 Torr to 500 Torr, from 0.01 Torr to 250 Torr, from 0.01 Torr to 200 Torr, from 0.01 Torr to 150 Torr, from 0.01 Torr to 100 Torr, from 0.01 Torr to 50 Torr, from 0.5 Torr to 760 Torr, from 0.5 Torr to 500 Torr, from 0.5 Torr to 250 Torr, from 0.5 Torr to 200 Torr, from 0.5 Torr to 150 Torr, from 0.5 Torr to 100 Torr, from 0.5 Torr to 50 Torr, from 1 Torr to 760 Torr, from 1 Torr to 500 Torr, from 1 Torr to 250 Torr, from 1 Torr to 200 Torr, from 1 Torr to 150 Torr, from 1 Torr to 100 Torr, from 1 Torr to 50 Torr, from 5 Torr to 760 Torr, from 5 Torr to 500 Torr, from 5 Torr to 250 Torr, from 5 Torr to 200 Torr, from 5 Torr to 150 Torr, from 5 Torr to 100 Torr, from 5 Torr to 50 Torr, from 10 Torr to 760 Torr, from 10 Torr to 500 Torr, from 10 Torr to 250 Torr, from 10 Torr to 200 Torr, from 10 Torr to 150 Torr, from 10 Torr to 100 Torr, from 10 Torr to 50 Torr, from 25 Torr to 760 Torr, from 25 Torr to 500 Torr, from 25 Torr to 250 Torr, from 25 Torr to 200 Torr, from 25 Torr to 150 Torr, from 25 Torr to 100 Torr, from 25 Torr to 50 Torr, from 50 Torr to 760 Torr, from 50 Torr to 500 Torr, from 50 Torr to 250 Torr, from 50 Torr to 200 Torr, from 50 Torr to 150 Torr, from 50 Torr to 100 Torr, from 100 Torr to 760 Torr, from 100 Torr to 500 Torr, from 100 Torr to 250 Torr, from 100 Torr to 200 Torr, from 100 Torr to 150 Torr, from 150 Torr to 760 Torr, from 150 Torr to 500 Torr, from 150 Torr to 250 Torr, from 150 Torr to 200 Torr, from 200 Torr to 760 Torr, from 200 Torr to 500 Torr or from 200 Torr to 250 Torr.

In one or more embodiments, the in situ annealing operation 331 is performed in an environment comprising the fluoride precursor and one or more of an inert gas (e.g., molecular nitrogen (N₂), argon (Ar)), a reducing gas (e.g., molecular hydrogen (H₂) or ammonia (NH₃)), an oxidant, such as, but not limited to, oxygen (O₂), ozone (O₃), or peroxides, and the fluoride precursor.

The annealing operation 331 can be performed for any suitable length of time. In one or more embodiments, the film is annealed for a predetermined time in the range of from 1 hour to 24 hour, from 1 hour to 20 hour, from 1 hour to 15 hour, from 1 hour to 10 hour, from 1 hour to 5 hour, from 5 hour to 24 hour, from 5 hour to 20 hour, from 5 hour to 15 hour, from 5 hour to 10 hour, from 10 hour to 24 hour, from 10 hour to 20 hour, from 10 hour to 15 hour, from 15 hour to 24 hour, from 15 hour to 20 hour or from 20 hour to 24 hour. In some embodiments, annealing the as-deposited film decreases the density, decreases the resistivity and/or increases the purity of the film.

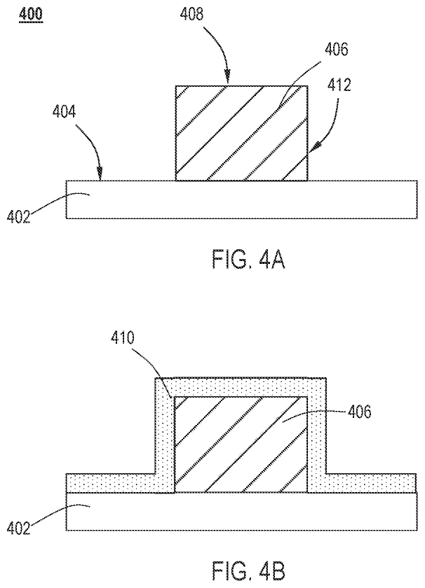

FIG. 4A illustrates a cross-sectional view of a device 400 according to one or more embodiments. In one or more embodiments, a feature 406 is formed on a top surface 404 of a substrate 402. The substrate 402 is provided for processing. As used in this specification and the appended claims, the term “provided” means that the substrate is made available for processing (e.g., positioned in a processing chamber). In some embodiments, the substrate 402 may comprise one or more of a semiconductor substrate, a processing chamber component, a workpiece, a pedestal, and a heater.

FIGS. 4A and 4B show substrates having a single feature for illustrative purposes; however, those skilled in the art will understand that there can be more than one feature. The shape of the feature 406 can be any suitable shape including, but not limited to, peaks, trenches, and vias. As used in this regard, the term “feature” means any intentional surface irregularity. Suitable examples of features include, but are not limited to trenches and vias, which have a top surface, at least one sidewall and a bottom surface, peaks which have a top surface 408 and at least one sidewall 412. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

Referring to FIG. 4B, a metal fluoride film 410 is deposited conformally on the top surface 404 of the substrate 402 and on the top surface 408 and on at least one sidewall 412 of the feature 406. In one or more embodiments, the metal fluoride film 110 is deposited according to one or more of the methods described herein.

In one or more embodiments, the metal fluoride film 410 comprises metal oxide with an oxygen content of less than or equal to about 5%, 7.5%, 10%, 12.5 or 15%, on an atomic basis. In some embodiments, the metal fluoride film has an oxygen content in the range of from 0.1% to 50%, from 2% to 30%, from 3% to 25% or from 4% to 20% on an atomic basis.

One or more embodiments of the disclosure are directed to methods of depositing metal fluoride films in high aspect ratio features. A high aspect ratio feature is a trench, via or pillar having a height:width ratio greater than or equal to about 10, 20, or 50, or more. In some embodiments, the metal fluoride film is deposited conformally on the high aspect ratio feature. As used in this manner, a conformal film has a thickness near the top of the feature that is in the range of about 80-120% of the thickness at the bottom of the feature.

Some embodiments of the disclosure are directed to methods for bottom-up gapfill of a feature. A bottom-up gapfill process fills the feature from the bottom versus a conformal process which fills the feature from the bottom and sides. In some embodiments, the feature has a first material at the bottom (e.g., a nitride) and a second material (e.g., an oxide) at the sidewalls. The metal fluoride film deposits selectively on the first material relative to the second material so that the metal fluoride film fills the feature in a bottom-up manner.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1

A silicon substrate was placed in a processing chamber. Tris(ethylcyclopentadienyl)yttrium was flowed into the processing chamber in an atmosphere of nitrogen (N₂) gas over the silicon substrate leaving a yttrium-terminated surface. Unreacted precursor and byproducts were then purged out of the chamber. Next, water (H₂O) was then introduced into the chamber and reacted with the yttrium species. Excess water and byproducts were removed from the chamber by purging. The resultant material on the substrate was a yttrium-oxide film. The process was repeated until the yttrium oxide film was about 200 nm thick. The yttrium oxide film was then annealed in an atmosphere of nitrogen trifluoride (NF₃) at a temperature of about 450° C. for about 4 hours to form a yttrium fluoride film on the substrate. The yttrium fluoride film had about 50% fluoride, about 30% yttrium, and about 20% oxygen in atomic %.

### Example 2

A silicon substrate is placed in a processing chamber. Bis(ethylcyclopentadienyl)calcium is flowed into the processing chamber in an atmosphere of nitrogen (N₂) gas over the silicon substrate leaving a calcium-terminated surface. Unreacted precursor and byproducts are then purged out of the chamber. Next, water (H₂O) is introduced into the chamber and reacted with the calcium species. Excess water and byproducts are removed from the chamber by purging. The resultant material on the substrate is a calcium-oxide film. The process is repeated until the calcium oxide film is about 200 nm thick. The calcium oxide film is then annealed in an atmosphere of nitrogen trifluoride (NF₃) at a temperature of about 600° C. for about 4-10 hours to form a calcium fluoride film on the substrate. The calcium fluoride film has about 50% fluoride, about 30% calcium, and about 20% oxygen in atomic %.

### Example 3

A silicon substrate is placed in a processing chamber. Bis(ethylcyclopentadienyl)barium is flowed into the processing chamber in an atmosphere of nitrogen (N₂) gas over the silicon substrate leaving a barium-terminated surface. Unreacted precursor and byproducts are then purged out of the chamber. Next, water (H₂O) is introduced into the chamber and reacted with the barium species. Excess water and byproducts are removed from the chamber by purging. The resultant material on the substrate is a barium-oxide film. The process is repeated until the barium oxide film is about 200 nm thick. The barium oxide film is then annealed in an atmosphere of nitrogen trifluoride (NF₃) at a temperature of about 600° C. for about 4-10 hours to form a barium fluoride film on the substrate. The barium fluoride film has about 50% fluoride, about 30% barium, and about 20% oxygen in atomic %.

### Example 4

A silicon substrate was placed in a processing chamber. Bis(ethylcyclopentadienyl)Mg was flowed into the processing chamber in an atmosphere of nitrogen (N₂) gas over the silicon substrate leaving a magnesium-terminated surface. Unreacted precursor and byproducts were then purged out of the chamber by flowing nitrogen (N₂). Next, ozone (O₃) was then introduced into the chamber and reacted with the magnesium species. Excess ozone and byproducts were removed from the chamber by purging. The resultant material on the substrate was a magnesium-oxide film. The magnesium-oxide film was then exposed to niobium fluoride (NbF₅) to form magnesium fluoride (MgF₂) on the substrate. Unreacted niobium fluoride and byproducts were then purged from the reaction chamber by flowing nitrogen (N₂). The process was repeated until the fluoride film was about 30 nm thick. The magnesium fluoride film had about 55% fluoride, about 35% magnesium, and about 10% oxygen in atomic %.

### Example 5

A silicon substrate is placed in a processing chamber. Bis(ethylcyclopentadienyl)calcium is flowed into the processing chamber in an atmosphere of nitrogen (N₂) gas over the silicon substrate leaving a calcium-terminated surface. Unreacted precursor and byproducts are then purged out of the chamber by flowing nitrogen (N₂). Next, ozone (O₃) is introduced into the chamber and reacted with the calcium species. Excess ozone and byproducts are removed from the chamber by purging. The resultant material on the substrate is a calcium-oxide film. The calcium-oxide film is exposed to niobium fluoride (NbF₅) to form calcium fluoride (CaF₂) on the substrate. Unreacted niobium fluoride and byproducts are purged from the reaction chamber by flowing nitrogen (N₂). The process is repeated until the fluoride film is about 30 nm thick. The calcium fluoride film has about 55% fluoride, about 35% calcium, and about 10% oxygen in atomic %.

### Example 6

A silicon substrate is placed in a processing chamber. Bis(ethylcyclopentadienyl)barium is flowed into the processing chamber in an atmosphere of nitrogen (N₂) gas over the silicon substrate leaving a barium-terminated surface. Unreacted precursor and byproducts are then purged out of the chamber by flowing nitrogen (N₂). Next, ozone (O₃) is introduced into the chamber and reacted with the barium species. Excess ozone and byproducts are removed from the chamber by purging. The resultant material on the substrate is a barium-oxide film. The barium-oxide film is exposed to niobium fluoride (NbF₅) to form barium fluoride (BaF₂) on the substrate. Unreacted niobium fluoride and byproducts are purged from the reaction chamber by flowing nitrogen (N₂). The process is repeated until the fluoride film is about 30 nm thick. The barium fluoride film has about 55% fluoride, about 35% barium, and about 10% oxygen in atomic %.

### Example 7

A silicon substrate was placed in a processing chamber. Bis(ethylcyclopentadienyl)Mg was flowed into the processing chamber in an atmosphere of nitrogen (N₂) gas over the silicon substrate leaving a magnesium-terminated surface. Unreacted precursor and byproducts were then purged out of the chamber by flowing nitrogen (N₂). Next, the substrate was exposed to niobium fluoride (NbF₅) to form a magnesium fluoride (MgF₂) film on the substrate. Unreacted niobium fluoride and byproducts were then purged from the reaction chamber by flowing nitrogen (N₂). The process was repeated until the magnesium-fluoride film was about 30 nm thick. The magnesium fluoride film had about 60% fluoride and about 40% magnesium in atomic %.

### Example 8

A silicon substrate is placed in a processing chamber. Bis(ethylcyclopentadienyl)calcium is flowed into the processing chamber in an atmosphere of nitrogen (N₂) gas over the silicon substrate leaving a calcium-terminated surface. Unreacted precursor and byproducts are then purged out of the chamber by flowing nitrogen (N₂). Next, the substrate is exposed to niobium fluoride (NbF₅) to form a calcium fluoride (CaF₂) film on the substrate. Unreacted niobium fluoride and byproducts are then purged from the reaction chamber by flowing nitrogen (N₂). The process is repeated until the calcium-fluoride film is about 30 nm thick. The calcium fluoride film has about 60% fluoride and about 40% calcium in atomic %.

### Example 9

A silicon substrate is placed in a processing chamber. Bis(ethylcyclopentadienyl)barium is flowed into the processing chamber in an atmosphere of nitrogen (N₂) gas over the silicon substrate leaving a barium-terminated surface. Unreacted precursor and byproducts are purged out of the chamber by flowing nitrogen (N₂). Next, the substrate is exposed to niobium fluoride (NbF₅) to form a barium fluoride (BaF₂) film on the substrate. Unreacted niobium fluoride and byproducts are purged from the reaction chamber by flowing nitrogen (N₂). The process is repeated until the barium-fluoride film is about 30 nm thick. The barium fluoride film has about 60% fluoride and about 40% barium in atomic %.

### Example 10

A silicon substrate was placed in a processing chamber. Bis(ethylcyclopentadienyl)Mg was flowed into the processing chamber in an atmosphere of nitrogen (N₂) gas over the silicon substrate leaving a magnesium-terminated surface. Unreacted precursor and byproducts were then purged out of the chamber by flowing nitrogen (N₂). Next, the substrate was exposed to titanium fluoride (TiF₄) to form a magnesium fluoride (MgF₂) film on the substrate. Unreacted titanium fluoride and byproducts were then purged from the reaction chamber by flowing nitrogen (N₂). The process was repeated until the magnesium-fluoride film was about 30 nm thick. The magnesium fluoride film had about 60% fluoride and about 40% magnesium in atomic %.

### Example 11

A silicon substrate is placed in a processing chamber. Bis(ethylcyclopentadienyl)calcium is flowed into the processing chamber in an atmosphere of nitrogen (N₂) gas over the silicon substrate leaving a calcium-terminated surface. Unreacted precursor and byproducts are purged out of the chamber by flowing nitrogen (N₂). Next, the substrate is exposed to titanium fluoride (TiF₄) to form a calcium fluoride (CaF₂) film on the substrate. Unreacted titanium fluoride and byproducts are purged from the reaction chamber by flowing nitrogen (N₂). The process is repeated until the calcium-fluoride film is about 30 nm thick. The calcium fluoride film has about 60% fluoride and about 40% calcium in atomic %.

### Example 12

A silicon substrate is placed in a processing chamber. Bis(ethylcyclopentadienyl)barium is flowed into the processing chamber in an atmosphere of nitrogen (N₂) gas over the silicon substrate leaving a barium-terminated surface. Unreacted precursor and byproducts are purged out of the chamber by flowing nitrogen (N₂). Next, the substrate is exposed to titanium fluoride (TiF₄) to form a barium fluoride (BaF₂) film on the substrate. Unreacted titanium fluoride and byproducts are purged from the reaction chamber by flowing nitrogen (N₂). The process is repeated until the barium-fluoride film is about 30 nm thick. The barium fluoride film has about 60% fluoride and about 40% barium in atomic %.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a metal fluoride film, the method comprising:
exposing a substrate surface to a metal precursor, the metal precursor volatile at a temperature at a temperature in a range of from 20° C. to 200° C.;
purging the substrate surface of the metal precursor;
exposing the substrate surface to a fluoride precursor to form the metal fluoride film, the fluoride precursor volatile at a temperature in a range of from 20° C. to 200° C.; and
purging the substrate surface of the fluoride precursor.

2. The method of claim 1, wherein the fluoride precursor comprises a volatile metal fluoride, F₂, HF, NH₄F, BF₃, SF₄, SF₆ plasma, NF₃ plasma, SOF₂, COF₂, POF₃, CIF₃, or combinations thereof.

3. The method of claim 2, wherein the volatile metal fluoride comprises TiF₄, NbF₅, TaF₅, VF₅, WF₆, WF₆, MoF₆, MoF₆, or combinations thereof.

4. The method of claim 1, wherein the metal precursor comprises one or more of metal alkyl compounds or derivatives thereof, metal allyl compounds or derivatives thereof, metal cyclopentadienyl compounds or derivatives thereof, metal amide compounds or derivatives thereof, metal amidine compounds or derivatives thereof, metal alkoxide compounds or derivatives thereof, metal aminoalkoxide compounds or derivatives thereof, and metal 1,4-diaza-1,3-diene compounds or derivatives thereof, the metal selected from the group consisting of Al, Mg, Ca, Sr, Ba, Sc, Y, Zr, Hf, La, Ce, Pr, Nd, Sm, Eu, Gd, Tb, Dy, Ho, Er, Tm, Yb, and combinations thereof.

5. The method of claim 1, wherein the method is repeated until the metal fluoride film has a thickness in a range of from 1 nm to 5000 nm.

6. A method of depositing a metal fluoride film, the method comprising:
exposing a substrate surface to a metal precursor, the metal precursor volatile at a temperature in a range of from 20° C. to 200° C.;
purging the substrate surface of the metal precursor;
exposing the substrate surface to an oxidizing agent at a temperature in a range of from 100° C. to 550° C.;
purging the substrate surface of the oxidizing agent;
exposing the substrate surface to a fluoride precursor at a temperature in a range of from 100° C. to 550° C. to form the metal fluoride film, the fluoride precursor volatile at a temperature in a range of from 20° C. to 200° C.; and
purging the reaction chamber of the fluoride precursor,
wherein the method is performed at a pressure in a range of from 0.01 Torr to 250 Torr.

7. The method of claim 6, wherein the fluoride precursor comprises a volatile metal fluoride, SOF₂, COF₂, POF₃, CIF₃, SF₄, R—SO₂F (e.g. perfluorobutanesulfonyl fluoride), N,N-diethylaminosulfur trifluoride (DAST), bis(2-methoxyethyl)-aminosulfur trifluoride (Deoxo-Fluor), 4-tert-butyl-2,6-dimethylphenylsulfur trifluoride (Fluolead), or combinations thereof.

8. The method of claim 7, wherein the volatile metal fluoride comprises TiF₄, NbF₅, TaF₅, VF₅, WF₆, WF₆, MoF₆, MoF₆, or combinations thereof.

9. The method of claim 6, wherein the metal precursor comprises one or more of metal alkyl compounds or derivatives thereof, metal allyl compounds or derivatives thereof, metal cyclopentadienyl compounds or derivatives thereof, metal amide compounds or derivatives thereof, metal amidine compounds or derivatives thereof, metal alkoxide compounds or derivatives thereof, metal alkoxide compounds or derivatives thereof, metal aminoalkoxide compounds or derivatives thereof, and metal 1,4-diaza-1,3-diene compounds or derivatives thereof, the metal selected from the group consisting of Al, Mg, Ca, Sr, Ba, Sc, Y, Zr, Hf, La, Ce, Pr, Nd, Sm, Eu, Gd, Tb, Dy, Ho, Er, Tm, Yb, and combinations thereof.

10. The method of claim 6, wherein the oxidant comprises H₂O, H₂O₂, O₂, O₂ plasma, ozone, or combinations thereof.

11. The method of claim 6, wherein the method is repeated until the metal fluoride film has a thickness in a range of from 1 nm to 5000 nm.

12. A method of forming a metal fluoride film, the method comprising:
exposing a substrate surface to a metal precursor;
purging the substrate surface of the metal precursor;
exposing the substrate surface to an oxidizing agent to form a metal oxide film;
purging the substrate surface of the oxidizing agent;
in situ annealing the metal oxide film in a fluoride precursor, the fluoride precursor volatile at a temperature in a range of from 20° C. to 200° C. to form a metal fluoride film.

13. The method of claim 12, wherein the metal precursor comprises one or more of metal alkyl compounds or derivatives thereof, metal allyl compounds or derivatives thereof, metal cyclopentadienyl compounds or derivatives thereof, metal amide compounds or derivatives thereof, metal amidine compounds or derivatives thereof, metal alkoxide compounds or derivatives thereof, metal aminoalkoxide compounds or derivatives thereof, and metal 1,4-diaza-1,3-diene compounds or derivatives thereof, the metal selected from the group consisting of Al, Mg, Ca, Sr, Ba, Sc, Y, Zr, Hf, La, Ce, Pr, Nd, Sm, Eu, Gd, Tb, Dy, Ho, Er, Tm, Yb, and combinations thereof.

14. The method of claim 12, wherein the oxidizing agent comprises H₂O, H₂O₂, O₂, O₂ plasma, ozone (O₃), or combinations thereof.

15. The method of claim 12, wherein the fluoride precursor comprises a volatile metal fluoride, SOF₂, COF₂, POF₃, CIF₃, SF₄, R—SO₂F (e.g. perfluorobutanesulfonyl fluoride), N,N-diethylaminosulfur trifluoride (DAST), bis(2-methoxyethyl)-aminosulfur trifluoride (Deoxo-Fluor), 4-tert-butyl-2,6-dimethylphenylsulfur trifluoride (Fluolead), or combinations thereof

16. The method of claim 12, wherein the fluoride precursor comprises NF₃, NF plasma, F₂, CIF₃, SOF₂, COF₂, POF₃, SF₆ plasma, SF₄ or combinations thereof.

17. The method of claim 12, wherein the method is repeated until the metal oxide film has a thickness in a range of from 1 nm to 5000 nm.

18. The method of claim 12, wherein the metal oxide film is annealed at a temperature in a range of from 100° C. to 700° C.

19. The method of claim 12, wherein the metal oxide film is annealed at a pressure in a range of from 0.5 Torr to 760 Torr.

20. The method of claim 12, wherein the metal oxide film is annealed for a time in a range of from 1 hour to 24 hours.
